(19) United States
(12) Patent Application Publication
(10) Pub. No.: US 2018/0083128 A1
(43) Pub. Date: Mar. 22, 2018

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Noboru YOKOYAMA, Kanazawa (JP); Yuhki FUJINO, Kanazawa (JP)

(73) Assignee: KABUSHIKI KAISHA TOSHIBA, Tokyo (JP)

(21) Appl. No.: 15/446,547

(22) Filed: Mar. 1, 2017

(30) Foreign Application Priority Data
Sep. 16, 2016 (JP) 2016-182006

(51) Int. Cl. H01L 29/739; H01L 27/06; H01L 21/8249; H01L 29/66; H01L 29/06; H01L 29/10; H01L 29/423

(52) U.S. Cl. CPC H01L 29/7395; H01L 27/0623; H01L 21/8249; H01L 29/42364; H01L 29/0642; H01L 29/1095; H01L 29/66333

(57) ABSTRACT

In some embodiments, according to one aspect, a semiconductor device includes a first semiconductor region of a first conductivity type that extends in a first direction, a second semiconductor region of a second conductivity type that is disposed adjacent to the first semiconductor region, extending in a second direction intersecting with the first direction, and having a surface which defines a first void in the second semiconductor region, a first insulating layer that is provided on the surface of the second semiconductor region which defines the first void, a third semiconductor region of the second conductivity type that is provided on the second semiconductor region and has a carrier concentration of the second conductivity type higher than a carrier concentration of the second conductivity type of the second semiconductor region, a fourth semiconductor region of the first conductivity type that is provided on the third semiconductor region, a gate insulating layer provided on the third semiconductor region, a gate electrode that faces the third semiconductor region through the gate insulating layer.

### CROSS-REFERENCE TO RELATED APPLICATION

This application claims the benefit and priority to Japanese Patent Application No. 2016-182006, filed Sep. 16, 2016, the entire contents of which are incorporated herein by reference.

### FIELD

Embodiments described herein relate generally to a semiconductor device and a method of manufacturing the same.

### BACKGROUND

A semiconductor device is provided having a super junction structure in which a p-type semiconductor region and an n-type semiconductor region are alternately arranged. In such a semiconductor device, it may be desirable to make a leak current small or to eliminate a leak current.

### SUMMARY

In some embodiments, according to one aspect, a semiconductor device includes a first semiconductor region of a first conductivity type that extends in a first direction, a second semiconductor region of a second conductivity type that is disposed adjacent to the first semiconductor region, extending in a second direction intersecting with the first direction, and having a surface which defines a first void in the second semiconductor region, a first insulating layer that is provided on the surface of the second semiconductor region which defines the first void, a third semiconductor region of the second conductivity type that is provided on the second semiconductor region and has a carrier concentration of the second conductivity type higher than a carrier concentration of the second conductivity type of the second semiconductor region, a fourth semiconductor region of the first conductivity type that is provided on the third semiconductor region, a gate insulating layer provided on the third semiconductor region, a gate electrode that faces the third semiconductor region through the gate insulating layer.

In some embodiments, according to another aspect, a method of manufacturing a semiconductor device includes providing a semiconductor substrate including a first semiconductor region of a first conductivity type that extends in a first direction, a second semiconductor region of a second conductivity type that is disposed adjacent to the first semiconductor region, extending in a second direction intersecting with the first direction, and having a surface which defines a first void in the second semiconductor region, a third semiconductor region of the second conductivity type that is provided on the second semiconductor region and has a carrier concentration of the second conductivity type higher than a carrier concentration of the second conductivity type of the second semiconductor region, a fourth semiconductor region of the first conductivity type that is provided on the third semiconductor region, a gate insulating layer provided on the third semiconductor region, and a gate electrode that faces the third semiconductor region via the gate insulating layer. The method further includes forming, in the semiconductor substrate, a trench that is connected to the first void, the trench positioned around the first semiconductor region, the second semiconductor region, the third semiconductor region, and the fourth semiconductor region, forming a first insulating layer on the surface of the second semiconductor region which defines the first void and on an inner wall of the trench, and forming a second insulating layer on the trench.

In some embodiments, according to another aspect, a semiconductor device includes a first semiconductor region of a first conductivity type that extends in a first direction, a second semiconductor region of a second conductivity type that is disposed adjacent to the first semiconductor region, extending in a second direction intersecting with the first direction, and having a surface which defines a void in the second semiconductor region, a third semiconductor region of the second conductivity type that is provided on the first semiconductor region, a fourth semiconductor region of the first conductivity type that is provided on the third semiconductor region, a fifth semiconductor region of the second conductivity type that is provided on the second semiconductor region and has a carrier concentration of the second conductivity type higher than a carrier concentration of the second conductivity type of the second semiconductor region, an insulating layer that is provided between the third semiconductor region and the fifth semiconductor region, agate insulating layer provided on the third semiconductor region, and agate electrode that faces the third semiconductor region via the gate insulating layer.

In some embodiments, according to another aspect, a method of manufacturing a semiconductor device includes providing a first semiconductor layer of a first conductivity type and defining a trench, forming an insulating layer on the first semiconductor layer such that a thickness of the insulating layer in an upper portion of the trench is thicker a thickness of the insulating layer in a lower portion of the trench, removing the insulating layer in the lower portion of the trench while leaving at least part of the insulating layer in the upper portion of the trench, forming a second semiconductor layer of a second conductivity type along an inner wall of the trench, and forming a third semiconductor layer on the second semiconductor layer, the third semiconductor layer defining a void located in the trench.

### BRIEF DESCRIPTION OF THE DRAWINGS

FIG. 1 is a plan view of embodiments of a semiconductor device according to a first aspect.

FIG. 2 is a cross-sectional view taken along a line A-A′ of FIG. 1.

FIG. 3 is a cross-sectional view taken along a line B-B′ of FIG. 1.

FIG. 4 is a plan view taken along a line C-C′ of FIG. 2.

FIG. 5 is a cross-sectional perspective view illustrating embodiments of a manufacturing process of the semiconductor device according to the first aspect.

FIG. 6 is a cross-sectional perspective view illustrating embodiments of a manufacturing process of the semiconductor device according to the aspect embodiment.

FIG. 7 is a cross-sectional perspective view illustrating embodiments of a manufacturing process of the semiconductor device according to the first aspect.

FIG. 8 is a plan view illustrating a process in a cross-section taken along a line D-D′ of FIG. 7.

FIG. 9 is a cross-sectional perspective view illustrating embodiments of a manufacturing process of the semiconductor device according to the first aspect.

FIG. 10 is a cross-sectional view illustrating part of the semiconductor device according to a modification of the first aspect.

FIG. 11 is a plan view of embodiments of a semiconductor device according to a second aspect.

FIG. 12 is a cross-sectional view taken along a line E-E′ of FIG. 11.

FIGS. 13A and 13B are cross-sectional views illustrating embodiments of a manufacturing process of the semiconductor device according to the second aspect.

FIGS. 14A and 14B are cross-sectional views illustrating embodiments of a manufacturing process of the semiconductor device according to the second aspect.

FIG. 15 is a cross-sectional view illustrating part of the semiconductor device according to a modification of the second aspect.

### DETAILED DESCRIPTION

Some embodiments described herein provide for a semiconductor device which can reduce a leak current, and a method of manufacturing the semiconductor device.

In general, according to some embodiments, a semiconductor device includes a first semiconductor region of a first conductivity type, a second semiconductor region of a second conductivity type, a first insulating layer, a third semiconductor region of the second conductivity type, a fourth semiconductor region of the first conductivity type, and a gate electrode. The first semiconductor region extends in a first direction. The second semiconductor region is adjacent to the first semiconductor region in a second direction intersecting with the first direction. The second semiconductor region includes a first void. The first insulating layer is provided on the surface of the first void. The third semiconductor region is provided on the second semiconductor region. A carrier concentration of the second conductivity type in the third semiconductor region is higher than a carrier concentration of the second conductivity type of the second semiconductor region. The fourth semiconductor region is provided on the third semiconductor region. The gate electrode faces the third semiconductor region via a gate insulating layer.

In the following description, embodiments will be described with reference to the drawings.

The drawings are illustrated schematically and conceptually, and a relation between thickness and width of the depicted components and/or devices, and a ratio of sizes between the depicted components and/or devices, are not necessarily illustrated to scale. Even in a case where a same component and/or device is illustrated, dimensions, extensions and ratios may be different than as illustrated in the drawings.

In the specification and the drawings of this application, some same reference symbols, letters or numerals are attached to the same element when that element has already been described, and detailed description may be omitted.

An XYZ orthogonal coordinate system is used in the explanation of embodiments described herein. For example, a direction where an n⁻ type pillar region 11 and a p⁻ type pillar region 12 are alternately arranged is set as an X direction, and a direction where the n⁻ type pillar region 11 and the p⁻ type pillar region 12 extend is set as a Y direction. A direction perpendicular to the X direction and the Y direction is set as a Z direction. This coordinate system and, at times, consistently described layout of devices and components is not meant to be limiting. Other arrangements and/or layouts of components and/or device may be used. As used herein, the term “upper” may be used to refer to a positive Z end of a component or device, and the term “lower” may be used to refer to a negative Z end of a component or device.

In the following explanation, the notations of n⁺, n⁻, p⁺, p, and p⁻ show relative magnitudes in impurity concentration in the respective conductivity types. In other words, the notation attached with “+” means that the impurity concentration is relatively higher than the notation that is not attached with “+”, and the notation attached with “−” means that the impurity concentration is relatively lower than the impurity concentration not attached with “−”.

In some embodiments, the disposition of the depicted p-type and the n-type of semiconductor regions may be swapped.

### (First Aspect)

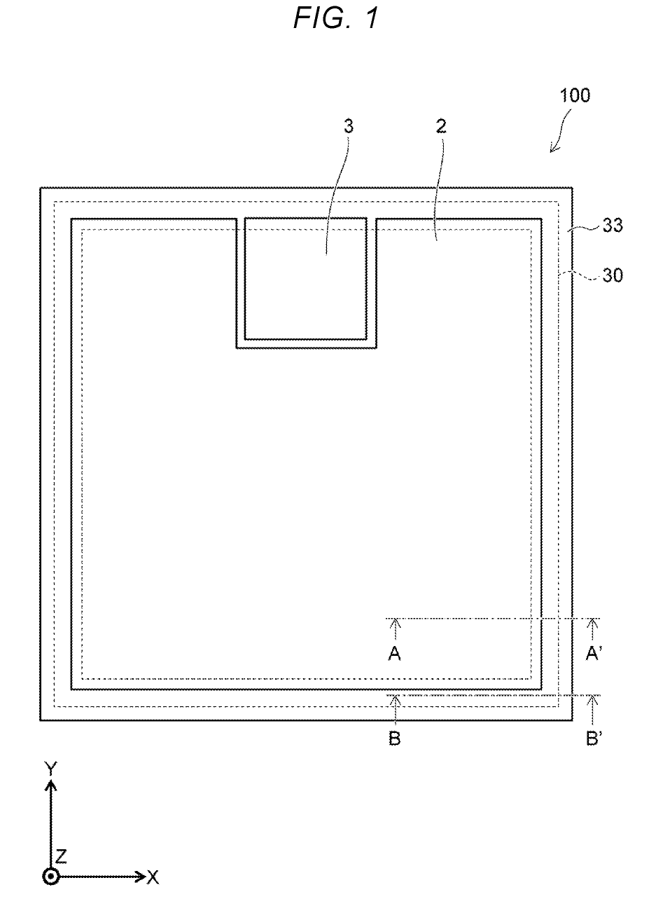

The following description relates to embodiments of a semiconductor device 100 according to a first aspect, and is described in reference to FIGS. 1 to 4.

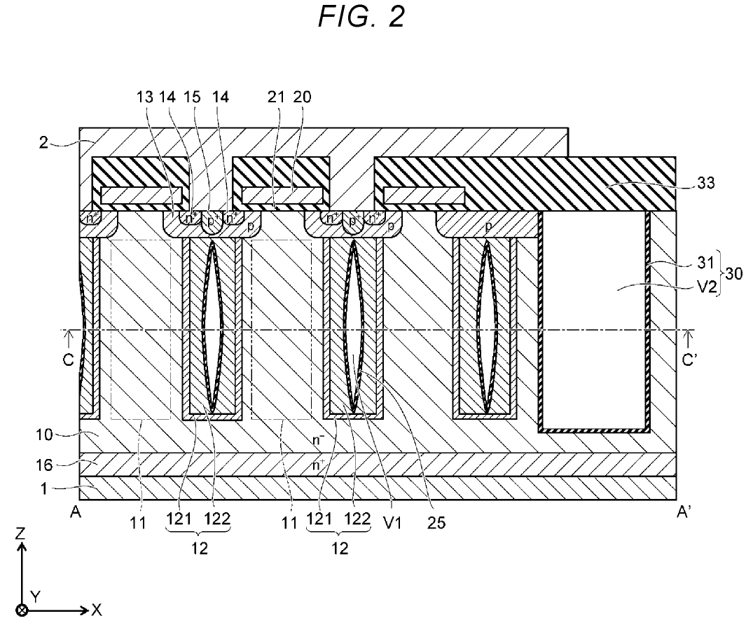

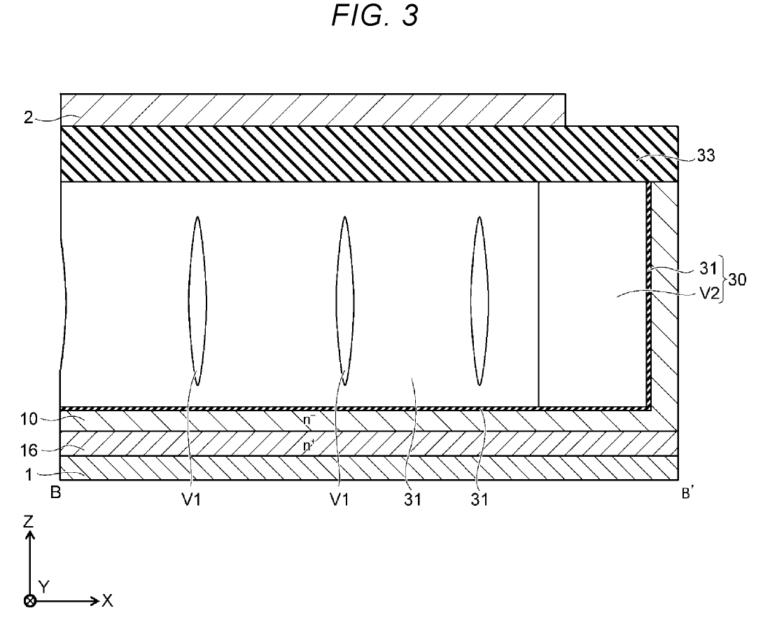

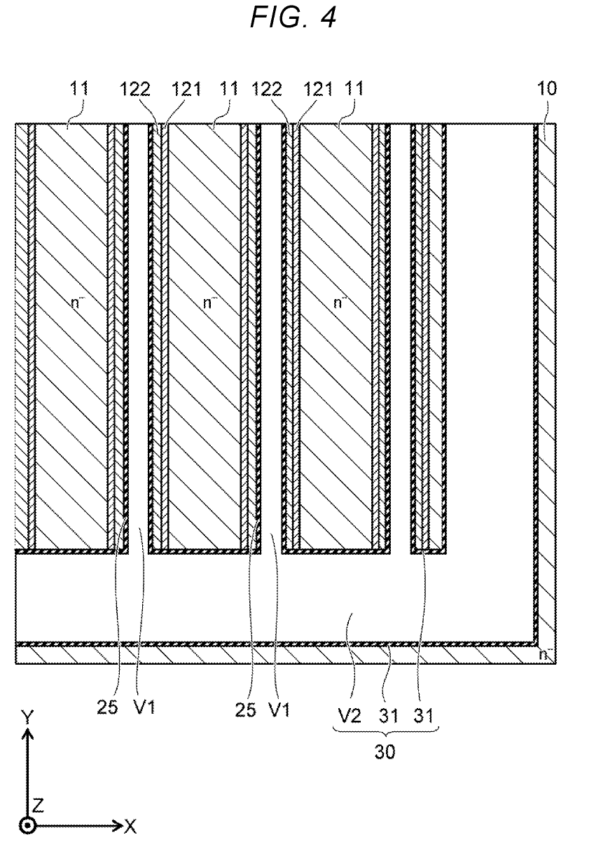

FIG. 1 is a plan view of embodiments of a semiconductor device 100 according to the first aspect. FIG. 2 is a cross-sectional view taken along a line A-A′ of FIG. 1. FIG. 3 is a cross-sectional view taken along a line B-B′ of FIG. 1. FIG. 4 is a plan view taken along a line C-C′ of FIG. 2.

As illustrated in FIGS. 1 to 4, the semiconductor device 100 includes a drain electrode 1, a source electrode 2, a gate pad 3, an n⁻ type (first conductivity type) semiconductor region 10, a p⁻ type (second conductivity type) pillar region 12 (second semiconductor region), a p-type base region 13 (third semiconductor region), an n⁺ type source region 14 (fourth semiconductor region), a p⁺ type contact region 15, an n⁺ type drain region 16, a gate electrode 20, a gate insulating layer 21, an insulating layer 25 (first insulating layer), a first insulating portion 30, a second insulating portion 33, and a void V1 (first void).

As illustrated in FIG. 1, the source electrode 2 and the gate pad 3 are provided on the upper surface of the semiconductor device 100 and are separated from each other. The first insulating portion 30 (illustrated as a broken line) is provided in an outer periphery of the semiconductor device 100 (e.g. in a substantially square shape, or in a substantially annular shape), and is disposed around the source electrode 2 and the gate pad 3 in plan view.

As illustrated in FIG. 2, the drain electrode 1 is provided on the lower surface of the semiconductor device 100. The n⁺ type drain region 16 is provided on the drain electrode 1, and is electrically connected to the drain electrode 1.

The n⁻ type semiconductor region 10 is provided on the n⁺ type drain region 16. The n⁻ type semiconductor region 10 includes a plurality of n⁻ type pillar regions 11 (first semiconductor regions). One or more p⁻ type pillar regions 12 are provided between the n⁻ type pillar regions 11 of the n⁻ type semiconductor region 10.

The n⁻ type pillar regions 11 and the p⁻ type pillar regions 12 extend in the Y direction, and are alternately arranged in the X direction. A super junction structure is formed by the n⁻ type pillar region 11 and the p⁻ type pillar region 12.

Each p⁻ type pillar region 12 defines and contains a void V1. The void V1 extends in the Y direction in the p⁻ type pillar region 12. An extension of the void V1 in the Z direction is longer than in the X direction. A width of the void V1 in the X direction is largest at or near a center of the p⁻ type pillar region 12 in the Z direction. The insulating layer 25 is provided at the edge of the void V1 (e.g. on the surfaces of the second region 122 which define the void V1). The insulating layer 25 is continuously provided in, for example, a substantially annular shape (which can be, for example, a substantially oval or substantially ellipse shape) in the X-Z plane, and extends in the Y direction.

Each p⁻ type pillar region 12 includes a first region 121 and a second region 122. The p-type impurity concentration in the second region 122 is lower than the p-type impurity concentration in the first region 121. At least part of the second region 122 may be a semiconductor region having no p-type impurity. The p-type impurity concentration in the first region 121 and in the second region 122 is set such that the p-type impurity amount contained in the p⁻ type pillar region 12 is the same or almost the same as the n-type impurity amount contained in the n⁻ type pillar region 11.

The first region 121 is provided along a boundary portion between the n⁻ type semiconductor region 10 and the p⁻ type pillar region 12. The second region 122 is provided inside a space defined by the first region 121 and the p-type base region 13, and the void V1 and the insulating layer 25 are located in the second region 122.

The p-type base region 13 is provided on the p⁻ type pillar region 12.

The n⁺ type source region 14 and the p⁺ type contact region 15 are provided on the p-type base region 13.

The gate electrode 20 is provided on the n⁻ type pillar region 11, a portion of the p-type base region 13, and a portion of the n⁺ type source region 14, and faces these semiconductor regions through the gate insulating layer 21. The gate electrode 20 is electrically connected to the gate pad 3 illustrated in FIG. 1.

The p-type base region 13, the n⁺ type source region 14, the p⁺ type contact region 15, and the gate electrode 20 can each or all be provided in plural places in the X direction (e.g. in a repeating pattern of disposition), and these regions and the electrode extend in the Y direction.

The source electrode 2 is electrically connected to the n⁺ type source region 14 and the p⁺ type contact region 15. The source electrode 2 is electrically separated from the gate electrode 20 by the gate insulating layer 21.

The first insulating portion 30 surrounds the n⁻ type pillar region 11, the p⁻ type pillar region 12, the p-type base region 13, the n⁺ type source region 14, and the p⁺ type contact region 15, and abuts then type semiconductor region 10 and the p-type base region 13. The first insulating portion 30 traverses the n⁻ type semiconductor region 10 and reaches to, or close to, the n⁺ type drain region 16, and may further surround part of the n⁺ type drain region 16.

The first insulating portion 30 includes an insulating layer 31 (second insulating layer) and contains and defines a void V2 (second void) located inside the insulating layer 31, for example. The second insulating portion 33 is provided on the first insulating portion 30, and covers a top side (a side furthest along the positive Z direction) of the void V2.

The insulating layer 25, the void V1, and the first insulating portion 30 are described below with respect to FIGS. 3 and 4.

The insulating layer 31 and the void V2 are provided in a substantially annular shape in the outer periphery of the semiconductor device 100. As illustrated in FIGS. 3 and 4, the void V2 is connected to a plurality of voids V1. In other words, the voids V1 and the void V2 may be portions of a single larger void. The insulating layer 25 provided on the surfaces of the second region 122 which define the void V1 is connected to the insulating layer 31 of the first insulating portion 30, and is provided continuously with the insulating layer 31.

An end of the n⁻ type pillar region 11 in the Y direction (the end further in the positive Y direction) and an end of the p⁻ type pillar region 12 in the Y direction (the end further in the positive Y direction) are connected to the insulating layer 31 of the first insulating portion 30.

An extension of the void V2 in the Z direction is longer an extension of the void V1 in the Z direction, for example. An extension of the void V2 in the Z direction is longer an extension of the p⁻ type pillar region 12 in the Z direction. A width of the void V2 is wider a width of the p⁻ type pillar region 12 in the X direction.

Some manners of operating the semiconductor device 100 are described below.

When a voltage equal to or more than a threshold is applied to the gate electrode 20 in a state where a voltage which is positive with respect to the source electrode 2 is applied to the drain electrode 1, a channel (inversion layer) is formed in a region near the gate insulating layer 21 of the p-type base region 13, and the semiconductor device 100 enters the ON state.

Thereafter, when a voltage applied to the gate electrode 20 is lower than the threshold, the channel in the p-type base region 13 disappears, and the semiconductor device 100 enters the OFF state.

When the semiconductor device 100 is in the OFF state and a voltage which is positive with respect to the source electrode 2 is applied to the drain electrode 1, a depletion layer is extended in the boundary between the n⁻ type pillar region 11 and the p⁻ type pillar region 12 and in a boundary between the n⁻ type pillar region 11 and the p-type base region 13. At this time the depletion layer is extended from the boundary between the n⁻ type pillar region 11 and the p⁻ type pillar region 12 in the X direction, and an electric field concentration between the n⁻ type pillar region 11 and the p-type base region 13 in the Z direction is suppressed, and thus a high breakdown voltage is obtained.

Next, examples of materials of the respective components will be described. Use of other materials in addition to, or in place of, the materials discussed below may be appropriate in some embodiments.

The drain electrode 1, the source electrode 2, and the gate pad 3 contain metal such as aluminum.

The n⁻ type semiconductor region 10, the p⁻ type pillar region 12, the p-type base region 13, the n⁺ type source region 14, the p⁺ type contact region 15, and the n⁺ type drain region 16 contain a semiconductor material such as silicon, for example. As an n-type impurity added to the semiconductor material, arsenic, phosphorus, or antimony may be used. As a p-type impurity, boron may be used.

The gate electrode 20 contains a conductive material such as polysilicon.

The gate insulating layer 21, the insulating layer 25, the insulating layer 31, and the second insulating portion 33 contain an insulating material such as a silicon oxide.

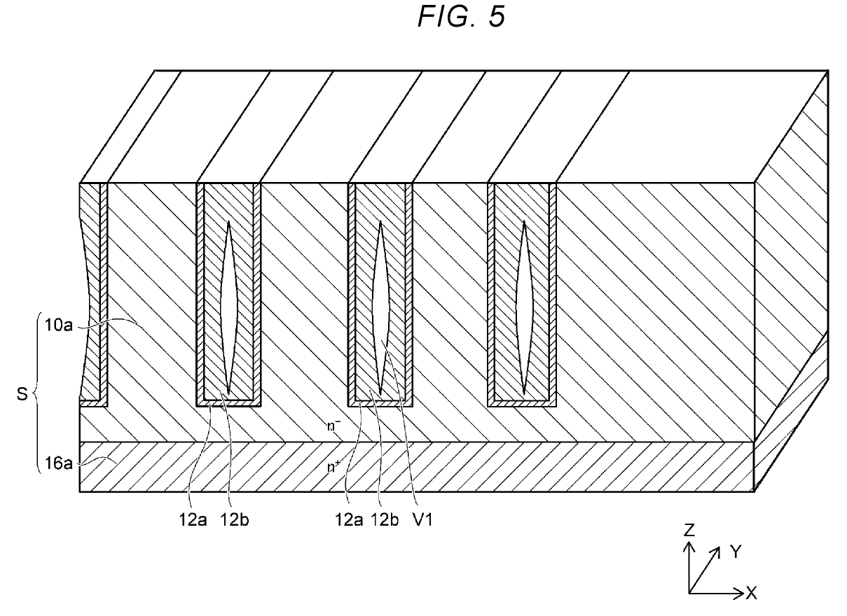

Next, some embodiments of a method of manufacturing the semiconductor device 100 according to the first aspect will be described with reference to FIGS. 5 to 9.

FIGS. 5 to 7 are cross-sectional perspective views illustrating some embodiments of a manufacturing processes of the semiconductor device 100 according to the first aspect.

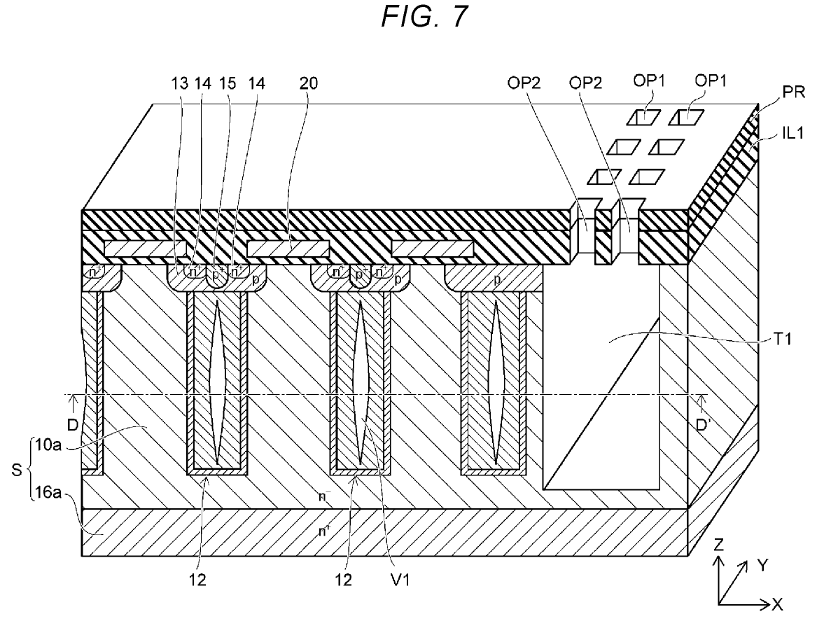

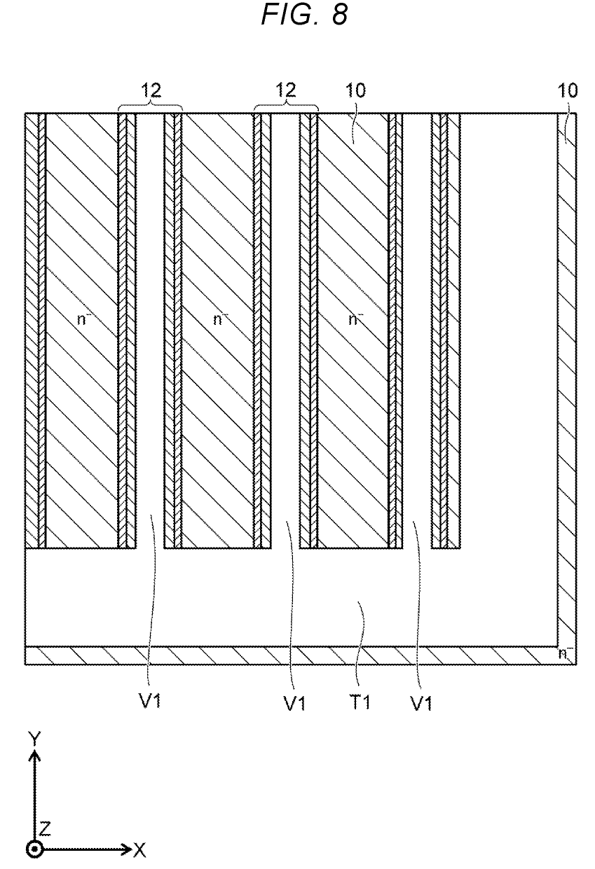

FIG. 8 is a plan view illustrating some embodiments of a process in a cross-section taken along a line D-D′ of FIG. 7.

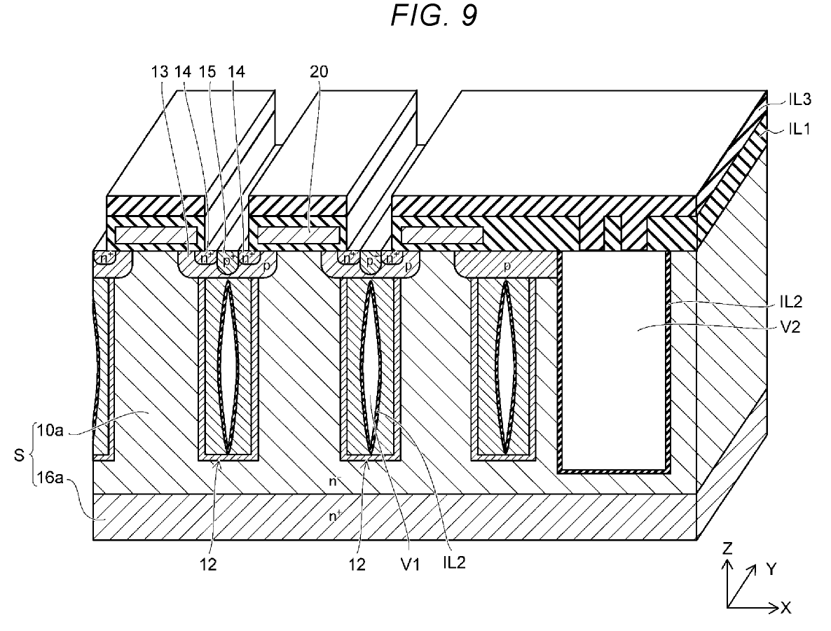

FIG. 9 is a cross-sectional perspective view illustrating some embodiments of a manufacturing process of the semiconductor device 100 according to the first aspect.

First, a semiconductor substrate S having an n⁺ type semiconductor layer 16a and an n⁻ type semiconductor layer 10a is prepared and/or provided. Next, a plurality of trenches extending in the Y direction are formed in the upper surface of the n⁻ type semiconductor layer 10a. Subsequently, a p⁻ type semiconductor layer 12a is epitaxially grown along the inner wall of the trench of the n⁻ type semiconductor layer 10a. As used herein, the term “inner wall” may refer to surfaces which define a trench. Subsequently, an undoped semiconductor layer 12b is formed on the p⁻ type semiconductor layer 12a and substantially fills the trench, except for a portion of the trench which corresponds to the void V1. Thus, the p⁻ type pillar region 12 having the void V1 is formed. Portion of the n⁻ type semiconductor layer 10a disposed between the p⁻ type pillar regions 12 correspond to the n⁻ type pillar regions 11 depicted in FIG. 2.

In the above process, the p⁻ type semiconductor layer 12a is formed at a relatively low growth rate, and the undoped semiconductor layer 12b is formed at a relatively high growth rate. In other words, the undoped semiconductor layer 12b is formed with a higher growth rate than is the p⁻ type semiconductor layer 12a. A difference between the upper and lower portions of the trench in terms of thicknesses of their respective semiconductor layers 12 can be made small by implementing a low growth rate for the p⁻ type semiconductor layer 12a. On the other hand, the void V1 is more easily formed in the semiconductor layer 12b by implementing a high growth rate for the semiconductor layer 12b.

When the growth rates of the p⁻ type semiconductor layer 12a and the semiconductor layer 12b are set to satisfy the above described relation (implementing a higher growth rate for the semiconductor layer 12b than for the semiconductor layer 12a), the total time taken for forming the p⁻ type pillar region 12 can be shortened while suppressing deviation in the p-type impurity amount in the respective portions of the p⁻ type pillar region 12.

Next, ions of the p-type impurity and the n-type impurity are implanted in predetermined regions of the upper surface of the n⁻ type semiconductor layer 10a to form the p-type base region 13, the n⁺ type source region 14, and the p⁺ type contact region 15.

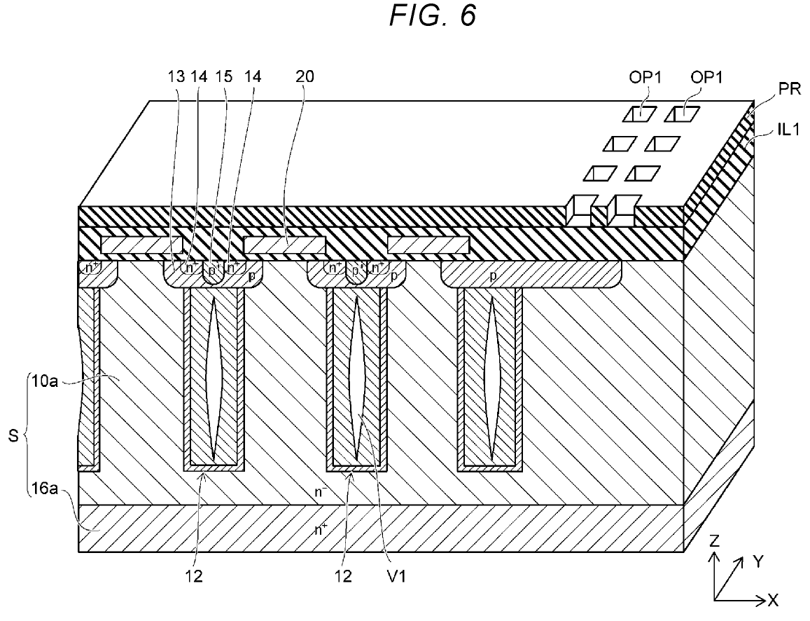

Next, as illustrated in FIG. 6, an insulating layer IL1 and the gate electrode 20 are formed on the n⁻ type semiconductor layer 10a, and a photoresist PR is formed on the insulating layer IL1. A plurality of openings OP1 are formed in the photoresist PR. The position of the openings OP1 correspond to the location where the first insulating portion 30 will be formed.

Next, as illustrated in FIG. 7, the insulating layer IL1 is patterned by a reactive ion etching (RIE) method using the photoresist PR as a mask to form a plurality of openings OP2 in the insulating layer IL1. Subsequently, the n⁻ type semiconductor layer 10a is etched using the photoresist PR and the insulating layer IL1 as a mask. At this time, an anisotropic etching and an isotropic etching are performed in combination to forma trench T1 below the plurality of openings OP1, as illustrated in FIG. 7, by a Bosch process. As illustrated in FIG. 8, the trench T1 is formed such that the voids V1 in the p⁻ type pillar regions 12 are exposed and the trench T1 and the voids V1 communicate with each other.

Next, the photoresist PR is removed by ashing. Subsequently, oxygen gas is supplied into the trench T1 and the void V1 through the opening OP2, and the semiconductor substrate is thermally oxidized. Thus, an insulating layer IL2 (first insulating layer) is formed on the inner wall of the trench T1 and on the surfaces of the second region 122 which define the void V1.

Next, an insulating layer IL3 (second insulating layer) is formed on the insulating layer IL1 by a Chemical Vapor Deposition (CVD) method. At this time, the trench T1 may be filled with the insulating layer IL3. Alternatively, the void V2 may be formed by covering the opening OP2 using the insulating layer IL3 before the trench T1 is completely filled. Subsequently, the insulating layer IL1 and the insulating layer IL3 are patterned, and the n⁺ type source region 14 and the p⁺ type contact region 15 are exposed. FIG. 9 illustrates the semiconductor device 100 at this stage in the manufacturing process. FIG. 9 depicts embodiments of the semiconductor device 100 in which the opening OP2 is covered by the insulating layer IL3, and the void V2 is formed.

Next, a metal layer is formed on the insulating layer IL3, and the source electrode 2 and the gate pad 3 are formed by patterning the metal layer. Subsequently, the n⁺ type semiconductor layer 16a is ground until the n⁺ type semiconductor layer 16a has a predetermined thickness. Then, the semiconductor device 100 as illustrated in FIGS. 1 to 4 is completed by forming the drain electrode 1 on the rear surface of the ground n⁺ type semiconductor layer 16a.

Some advantages of the semiconductor device 100 according to the first aspect are described below.

First, as a reference example, description will be given about a semiconductor device which has a similar structure as that of the semiconductor device 100, except that the insulating layer 25 is not formed such that it surrounds and/or defines the voids V1.

In the semiconductor device according to the reference example, a dangling bond of the semiconductor material contained in the p⁻ type pillar region 12 may exist at an edge of at least one void V1. Therefore, a leak current may flow between the drain electrode 1 and the source electrode 2 via the dangling bond when the semiconductor device is in the OFF state. When the leak current flows, a power consumption and a heat quantity of the semiconductor device are increased, and thus the leak current is desirably made small or eliminated.

In embodiments of the semiconductor device 100 according to the first aspect, the insulating layer 25 is formed around an edge of the void V1, or may define the void V1, and may help to make the leak current small or to eliminate the leak current. The dangling bond of the semiconductor material contained in the p⁻ type pillar region 12 is substantially eliminated by the insulating layer 25. Therefore, when the semiconductor device 100 is in the OFF state, the leak current flowing to the semiconductor device 100 through the void V1 or near an edge of the void V1 is reduced or eliminated, and the power consumption and the heat quantity of the semiconductor device can be reduced.

In embodiments of the semiconductor device 100 according to the first aspect, the first insulating portion 30 is formed and surrounds the n⁻ type pillar region 11, the p⁻ type pillar region 12, the p-type base region 13, the n⁺ type source region 14, and the p⁺ type contact region 15. The n⁻ type semiconductor region 10 and the p-type base region 13 are in contact with the first insulating portion 30.

When the semiconductor device is in the OFF state, an electric field in the vicinity of the outer periphery of the p-type base region 13 can form or can increase in intensity. However, due to the structure of the semiconductor device 100, the electric field concentrates in the first insulating portion 30. Therefore, a region useful for preventing an avalanche breakdown around the p-type base region 13 can be reduced in size, and thus the semiconductor device can be miniaturized.

The p⁻ type pillar region 12 extends in the Y direction as illustrated in FIG. 4, and is in contact with the first insulating portion 30. Since the p⁻ type pillar region 12 extends in the Y direction and contacts the first insulating portion 30, a region between the n⁻ type semiconductor region 10 (e.g. the n⁻ type pillar region 11) and the p⁻ type pillar region 12 is further depleted even in the vicinity of the first insulating portion 30, and a breakdown voltage of the semiconductor device can be desirably increased.

In some semiconductor devices, the void V2 of the first insulating portion 30 may be filled with an insulating material. In this case, a dielectric constant of the insulating material, such as silicon oxide or silicon nitride, is greater than a dielectric of air or vacuum which fills the void V2. Thus, when the void V2 is formed, the thickness of the first insulating portion 30 necessary for obtaining a predetermined breakdown voltage can be made thin compared to a case where the void V2 is filled with the insulting material. Therefore, the semiconductor device can be miniaturized.

The void V1 desirably extends in the Y direction in the p⁻ type pillar region 12, and reaches to the first insulating portion 30, connecting to the void V2.

Next, advantages of embodiments of the method of manufacturing the semiconductor device according to the first aspect will be described.

In embodiments of the method of manufacturing the semiconductor device according to the first aspect, the trench T1 is formed in the semiconductor substrate S in which the n⁻ type pillar region 11, the p⁻ type pillar region 12, the p-type base region 13, the n⁺ type source region 14, and the gate electrode 20 are formed. At this time, the trench T1 is formed and surrounds the n⁻ type pillar region 11, the p⁻ type pillar region 12, the p-type base region 13, and the n⁺ type source region 14, and to be connected to the void V1. Then, the oxygen gas is supplied to the void V1 through the trench T1, and the insulating layer is formed on surfaces of the second region 122 which define the void V1.

According to such a manufacturing method, substantially all of the surfaces of the second region 122 which define the void V1 can be oxidized, and the leak current of the manufactured semiconductor device can be effectively reduced.

### (Modification)

In the example illustrated in FIGS. 1 to 4, the semiconductor device has a planar gate structure in which the gate electrode 20 is provided on the semiconductor region via the gate insulating layer 21. The structure is not limited to this example. Embodiments of the semiconductor device according to the first aspect may have a trench gate structure in which the gate electrode 20 is provided in the semiconductor region via the gate insulating layer 21.

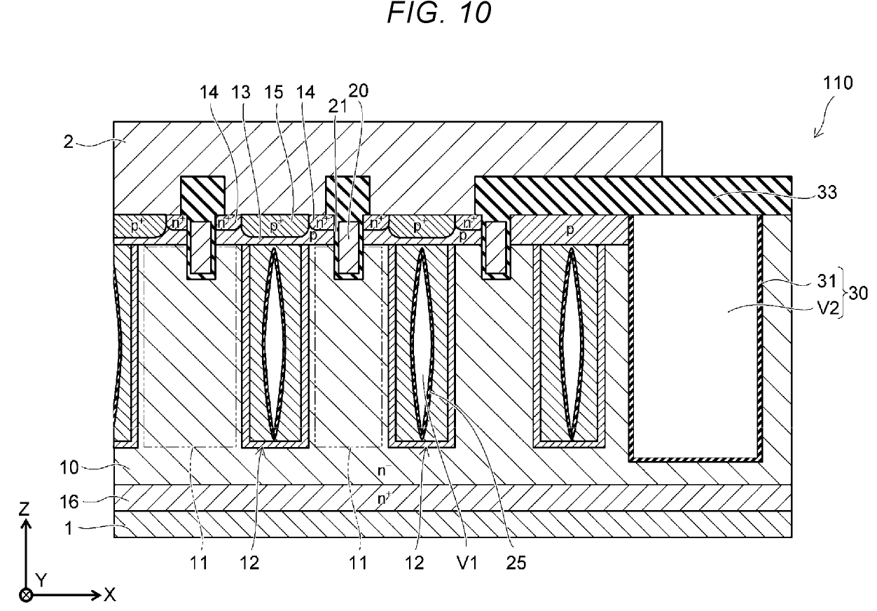

FIG. 10 is a cross-sectional view illustrating part of a semiconductor device 110 according to a modification of embodiments of the first aspect. In the semiconductor device 110, the gate electrode 20 is provided on each n⁻ type pillar region 11, and extends in the Y direction. A surface of the gate electrode 20 which extends in the X direction faces part of the n⁻ type pillar region 11, the p-type base region 13, and the n⁺ type source region 14 via the gate insulating layer 21.

In this modification, as in other embodiments described herein, the insulating layer 25 is provided on the surfaces of the second region 122 which define the void V1 of the p⁻ type pillar region 12. Therefore, it is possible to reduce the leak current when the semiconductor device is in the OFF state.

### (Second Aspect)

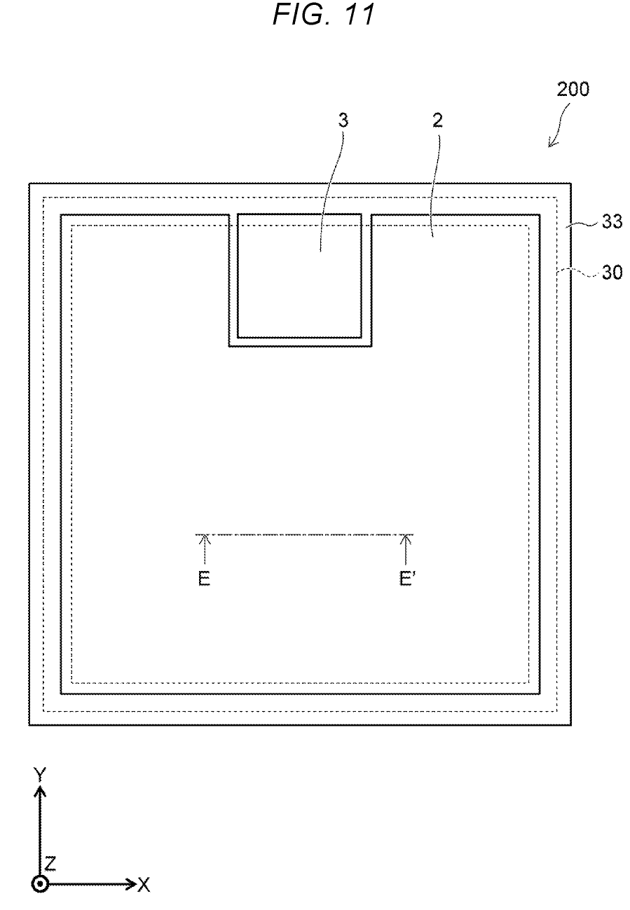

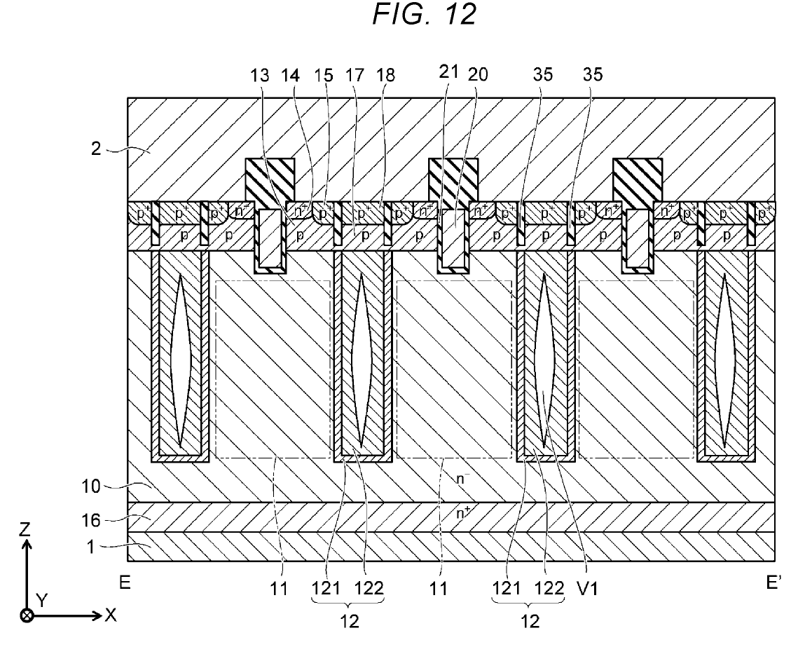

Next, description will be given about embodiments of a semiconductor device 200 according to a second aspect with reference to FIGS. 11 and 12.

Components similar to those described above in reference to the first aspect will be referred to with the same reference symbols, letter and numerals, and description thereof may be omitted.

FIG. 11 is a plan view of embodiments of the semiconductor device 200 according to the second aspect.

FIG. 12 is a cross-sectional view taken along a line E-E′ of FIG. 11.

As illustrated in FIGS. 11 and 12, embodiments of the semiconductor device 200 include the drain electrode 1, the source electrode 2, the gate pad 3, the n⁺ type drain region 16, the n⁻ type semiconductor region 10, the p⁻ type pillar region 12 (second semiconductor region), the p-type base region 13 (third semiconductor region), the n⁺ type source region 14 (fourth semiconductor region), the p⁺ type contact region 15, a p-type semiconductor region 17 (fifth semiconductor region), a p⁺ type semiconductor region 18 (sixth semiconductor region), the gate electrode 20, the gate insulating layer 21, the first insulating portion 30, the second insulating portion 33, an insulating layer 35, and the void V1. The first insulating portion 30 is illustrated by a broken line in FIG. 11.

As illustrated in FIG. 11, the first insulating portion 30 is provided in an outer periphery of the semiconductor device 200 similarly to how it is disposed in the semiconductor device 100, and is covered by the second insulating portion 33. In this case, part of the n⁻ type semiconductor region 10 may be provided in place of the first insulating portion 30.

As illustrated in FIG. 12, then type pillar region 11 (first semiconductor region) and the p⁻ type pillar region 12 are alternately provided along the X direction in the semiconductor device 200 similarly to how they are provided in the semiconductor device 100.

The p⁻ type pillar region 12 includes the first region 121 and the second region 122 in which the p-type impurity concentration is lower than the p-type impurity concentration in the first region 121. The second region 122 is provided inside the first region 121, and contains and defines the void V1.

The p-type base region 13 is provided on the n⁻ type pillar region 11.

The n⁺ type source region 14 and the p⁺ type contact region 15 are provided on the p-type base region 13.

The gate electrode 20 faces part of the n⁻ type pillar region 11, the p-type base region 13, and the n⁺ type source region 14 via the gate insulating layer 21.

The p-type semiconductor region 17 is provided on the p⁻ type pillar region 12.

The p⁺ type semiconductor region 18 is provided on the p-type semiconductor region 17.

The insulating layer 35 is provided between the p-type semiconductor region 17 and the p-type base region 13, and between the p⁺ type semiconductor region 18 and the p⁺ type contact region 15 (e.g. above a boundary between the n⁻ type pillar region 11 and the p⁻ type pillar region 12).

An upper end of the void V1 (an end furthest in the positive Z direction) is positioned lower than (more in the negative z direction) a lowest end of the insulating layer 35, for example.

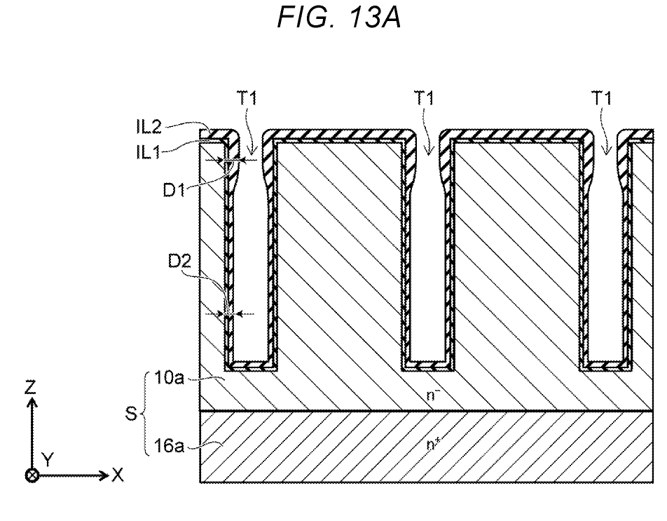

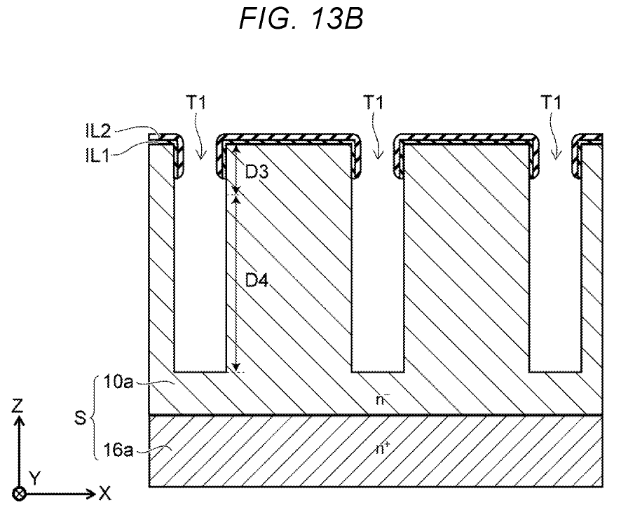

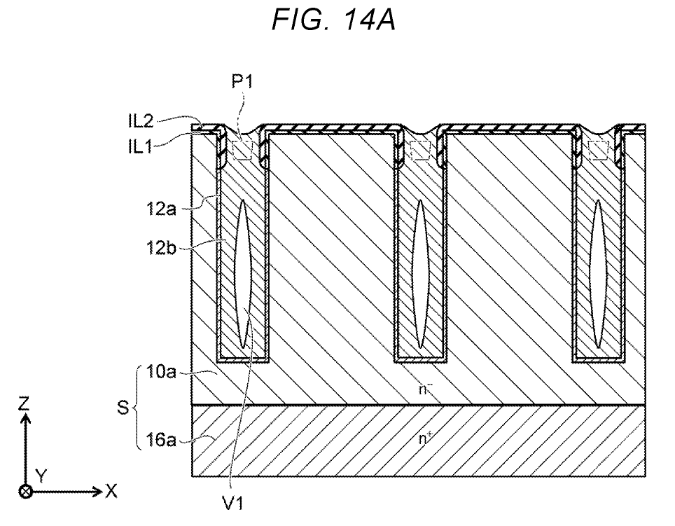

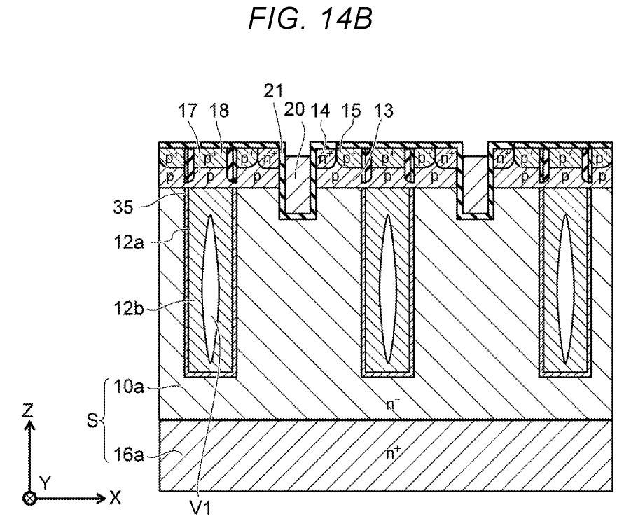

Next, description will be given about embodiments of a method of manufacturing the semiconductor device 200 according to the second aspect with reference to FIGS. 13A to 14B.

FIGS. 13A to 14B are cross-sectional views illustrating embodiments of method of manufacturing the semiconductor device 200 according to the second aspect.

First, the semiconductor substrate having the n⁺ type semiconductor layer 16a and the n⁻ type semiconductor layer 10a (first semiconductor layer) is prepared and/or provided. Next, a plurality of trenches T1 extending in the Y direction are formed in an upper surface of the n⁻ type semiconductor layer 10a. Subsequently, the semiconductor substrate is thermally oxidized and thus the insulating layer IL1 is formed on the upper surface of the n⁻ type semiconductor layer 10a.

Next, the insulating layer IL2 is formed on the insulating layer IL1. The insulating layer IL2 can be formed using a method which does not necessarily produce uniform layers on stepped surfaces. As such a method, an atmospheric pressure CVD method can be used, for example. As a result, as illustrated in FIG. 13A, a thickness D1 of the insulating layers IL1 and IL2 formed in the upper portion of the trench T1 is thicker than a thickness D2 of the insulating layers IL1 and IL2 formed in the lower portion of the trench T1.

Next, an isotropic etching method such as a wet etching method or a chemical dry etching (CDE) method is performed on the insulating layers IL1 and IL2. Therefore, as illustrated in FIG. 13B, the insulating layer formed in the lower portion of the trench T1 is removed while leaving at least part of the insulating layer formed in the upper portion of the trench T1.

After the insulating layer of the lower portion of the trench T1 is removed, an extension D3 of the insulating layers IL1 and IL2 in a depth direction (Z direction) of the trench T1 becomes shorter than an extension D4 of a portion not covered by the insulating layers IL1 and IL2 of the trench T1 in the Z direction, for example.

Next, the p⁻ type semiconductor layer 12a (second semiconductor layer) is epitaxially grown along an inner wall of the trench T1. At this time, an upper portion of the trench T1 is covered by the insulating layers IL1 and IL2. Therefore, the p⁻ type semiconductor layer 12a is not grown in an upper portion of the trench T1 covered by the insulating layers IL1 and IL2, but is grown in a bottom portion of the trench T1. Subsequently, as illustrated in FIG. 14A, the undoped semiconductor layer 12b (third semiconductor layer) defining the void V1 is epitaxially grown on the p⁻ type semiconductor layer 12a. At first, the semiconductor layer 12b is grown on the p⁻ type semiconductor layer 12a of the bottom portion of the trench T1. Thereafter, the semiconductor layer 12b is grown in the Z direction toward the upper portion of the trench T1.

Thus, the p⁻ type pillar region 12 containing and/or defining the void V1 is formed. In a portion P1 surrounded by the insulating layers IL1 and IL2 in the semiconductor layer 12b, a density of crystal defects is higher a density of crystal defects of other portions of the semiconductor layer 12b. The crystal defects are rectified by heating the upper surface of the semiconductor layer 12b by a laser annealing, and the crystal defect density in the portion P1 can thus be lowered.

Next, the insulating layers IL1 and IL2 covering the upper surface of the n⁻ type semiconductor layer 10a are removed. At this time, the insulating layers IL1 and IL2 left between the n⁻ type semiconductor layer 10a and the p⁻ type pillar region 12 correspond to the insulating layer 35 illustrated in FIG. 12. Subsequently, the upper surfaces of the n⁻ type semiconductor layer 10a and the p⁻ type pillar region 12 are planarized. Subsequently, ions of the p-type impurity are implanted in the upper surfaces of the n⁻ type semiconductor layer 10a and the p⁻ type pillar region 12, and the p-type base region 13 and the p-type semiconductor region 17 are formed.

Next, the trench is formed in the n⁻ type semiconductor layer 10a between the p⁻ type pillar regions 12, and the gate insulating layer 21 and the gate electrode 20 are formed inside the trench. Subsequently, ions of the n-type impurity and the p-type impurity are sequentially implanted in the upper surfaces of the n⁻ type semiconductor layer 10a and the p⁻ type pillar region 12. As illustrated in FIG. 14B, the n⁺ type source region 14, the p⁺ type contact region 15, and the p⁺ type semiconductor region 18 are formed.

Next, an insulating layer covering the gate electrode 20 (and possibly at least some portion of at least one of the n⁺ type source region 14, the p⁺ type contact region 15, and the p-type semiconductor region 18) is formed. The insulating layer may be co-extensive with the gate insulating layer 21. Then the insulating layer and part of the gate insulating layer 21 are removed so that the n⁺ type source region 14, the p⁺ type contact region 15, and the p-type semiconductor region 18 are exposed. Subsequently, a metal layer is formed on these semiconductor regions, and patterned to form the source electrode 2 and the gate pad 3. Subsequently, the n⁺ type semiconductor layer 16a is ground until the n⁺ type semiconductor layer 16a has a predetermined thickness. Then, the semiconductor device 200 illustrated FIGS. 11 and 12 is finalized by forming the drain electrode 1 on the rear surface of the ground n⁺ type semiconductor layer 16a.

Herein, advantages of embodiments according to the second aspect will be described.

The embodiments of the manufacturing method according to the second aspect includes a process of forming the insulating layer of which a thickness in the upper portion of the trench T1 is thicker than a thickness in the lower portion of the trench T1, a process of removing the insulating layer in the lower portion of the trench T1 while leaving the insulating layer in the upper portion of the trench T1, and a process of forming the p⁻ type semiconductor layer 12a, which defines the void V1 and in which the void V1 is provided, in the trench T1.

According to such a manufacturing method, when the p⁻ type semiconductor layer 12a and the semiconductor layer 12b are formed, the semiconductor material is not epitaxially grown from the side wall of the upper portion of the trench T1 covered by the insulating layer, but the semiconductor material is epitaxially grown in the lower portion from the insulating layer. Therefore, it is possible to lower the position of the upper end of the void V1 compared to a case where the p⁻ type semiconductor layer 12a and the semiconductor layer 12b are formed without forming the insulating layer in the upper portion of the trench T1.

In a case where the upper end of the void V1 is positioned high, grinding may be performed near or at the upper end of the void V1 in the planarization process. This may expose the void V1 to ambient air, for example. When the void V1 is exposed to the ambient air, impurities attach to the surfaces of the second region 122 which define the void V1, or an unintended compound may be formed, and thus the performance of the semiconductor device may be degraded.

However, according to some described embodiments, the position of the upper end of the void V1 can be lowered. Therefore, it is possible to reduce a possibility that the void V1 opened by grinding and exposed to the ambient air. In other words, according to this embodiment, it is possible to improve a manufacturing yield of the semiconductor device.

The position of the upper end of the void V1 can be adjusted by changing the extension D3 illustrated in FIG. 13B. In other words, the position of the upper end of the void V1 can be lowered as the extension D3 is made longer.

However, the thickness (extension in the Z direction) of the portion P1 surrounded by the insulating layers IL1 and IL2 in the semiconductor layer 12b, in which the crystal defect density is high, may also increase as the extension D3 becomes longer. When the portion P1 becomes too thick, it can be difficult to rectify the crystal defects through heating treatment. The extension D3 is desirably made shorter than the extension D4 in order to help ensure that the crystal defects of the portion P1 can be sufficiently rectified in the heating treatment, while still lowering the position of the upper end of the void V1.

### (Modification)

In the embodiments illustrated in FIGS. 11 and 12, the semiconductor device has a trench gate structure in which the gate electrode 20 is provided in the semiconductor region via the gate insulating layer 21. The structure of the semiconductor device is not limited to that described with respect to those embodiments.

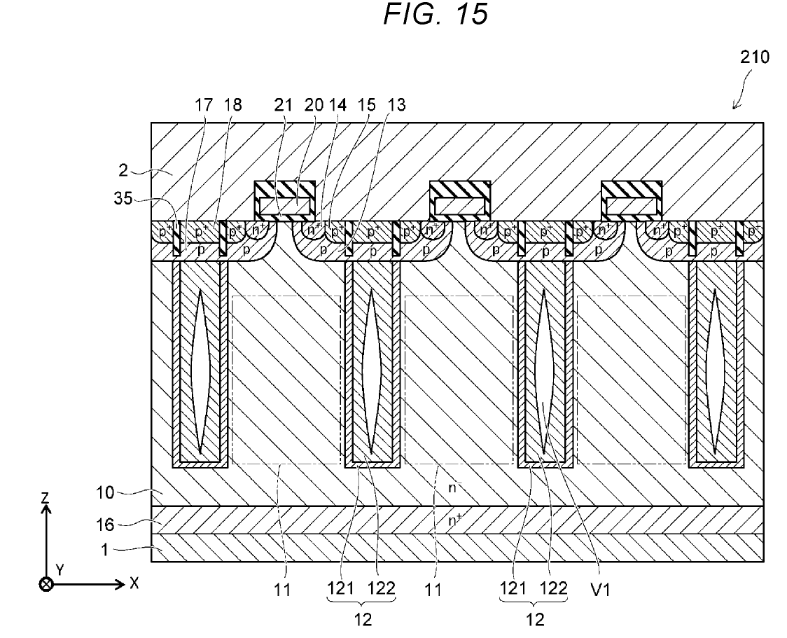

FIG. 15 is a cross-sectional view illustrating part of embodiments of a semiconductor device 210 according to a modification of the second aspect.

In the semiconductor device 210, the gate electrode 20 is provided on the n⁻ type pillar region 11, the p-type base region 13, and the n⁺ type source region 14 via the gate insulating layer 21.

In the embodiments described herein, a relative magnitude of the impurity concentration between the respective semiconductor regions may be confirmed using a scanning capacitance microscopy (SCM), for example. The carrier concentration in each semiconductor region may be close to, or substantially equal to the concentration of the activated impurity in the semiconductor region. Therefore, the relative magnitude of the carrier concentration between the respective semiconductor regions may be confirmed using the SCM.

The impurity concentration in each semiconductor region may be measured by a secondary ion mass spectrometry (SIMS), for example.

In the description of some embodiments, a component provided “on” another component can encompass cases where the former component is directly on (e.g., in physical contact with) the latter component, as well as cases where one or more intervening components are located between the former component and the latter component.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure. Moreover, some or all of the above described embodiments can be combined when implemented.

What is claimed is:

1. A semiconductor device, comprising:
a first semiconductor region of a first conductivity type that extends in a first direction;
a second semiconductor region of a second conductivity type that is disposed adjacent to the first semiconductor region, extending in a second direction intersecting with the first direction, and having a surface which defines a first void in the second semiconductor region;
a first insulating layer that is provided on the surface of the second semiconductor region which defines the first void;
a third semiconductor region of the second conductivity type that is provided on the second semiconductor region and has a carrier concentration of the second conductivity type higher than a carrier concentration of the second conductivity type of the second semiconductor region;
a fourth semiconductor region of the first conductivity type that is provided on the third semiconductor region;
a gate insulating layer provided on the third semiconductor region; and
a gate electrode that faces the third semiconductor region through the gate insulating layer.

2. The semiconductor device according to claim 1, further comprising:
an insulating portion that surrounds the first semiconductor region, the second semiconductor region, the third semiconductor region, and the fourth semiconductor region;
wherein the insulating portion defines a second void that is connected to the first void.

3. The semiconductor device according to claim 2,
wherein an end of the first semiconductor region and an end of the second semiconductor region each come into contact with the insulating portion.

4. The semiconductor device according to claim 2,
wherein the insulating portion includes a second insulating layer that is provided around and defines the second void, and
wherein the first insulating layer is provided continuously to the second insulating layer.

5. A method of manufacturing a semiconductor device, the method comprising:
providing a semiconductor substrate including:
a first semiconductor region of a first conductivity type that extends in a first direction,
a second semiconductor region of a second conductivity type that is disposed adjacent to the first semiconductor region, extending in a second direction intersecting with the first direction, and having a surface which defines a first void in the second semiconductor region,
a third semiconductor region of the second conductivity type that is provided on the second semiconductor region and has a carrier concentration of the second conductivity type higher than a carrier concentration of the second conductivity type of the second semiconductor region,
a fourth semiconductor region of the first conductivity type that is provided on the third semiconductor region,
a gate insulating layer provided on the third semiconductor region; and
a gate electrode that faces the third semiconductor region via the gate insulating layer;
forming, in the semiconductor substrate, a trench that is connected to the first void, the trench positioned around the first semiconductor region, the second semiconductor region, the third semiconductor region, and the fourth semiconductor region;
forming a first insulating layer on the surface of the second semiconductor region which defines the first void and on an inner wall of the trench; and
forming a second insulating layer on the trench.

6. A semiconductor device, comprising:
a first semiconductor region of a first conductivity type that extends in a first direction;
a second semiconductor region of a second conductivity type that is disposed adjacent to the first semiconductor region, extending in a second direction intersecting with the first direction, and having a surface which defines a void in the second semiconductor region;
a third semiconductor region of the second conductivity type that is provided on the first semiconductor region;
a fourth semiconductor region of the first conductivity type that is provided on the third semiconductor region;
a fifth semiconductor region of the second conductivity type that is provided on the second semiconductor region and has a carrier concentration of the second conductivity type higher than a carrier concentration of the second conductivity type of the second semiconductor region;
an insulating layer that is provided between the third semiconductor region and the fifth semiconductor region;
a gate insulating layer provided on the third semiconductor region; and
a gate electrode that faces the third semiconductor region via the gate insulating layer.

7. The semiconductor device according to claim 6, further comprising:
a sixth semiconductor region of the second conductivity type that is provided on the fifth semiconductor region and has a carrier concentration of the second conductivity type higher than a carrier concentration of the second conductivity type of the fifth semiconductor region.

8. The semiconductor device according to claim 7,
wherein at least part of the insulating layer is provided between the first semiconductor region and the second semiconductor region.

9. The semiconductor device according to claim 6,
wherein at least part of the insulating layer is provided between the first semiconductor region and the second semiconductor region.

10. A method of manufacturing a semiconductor device, comprising:
providing a first semiconductor layer of a first conductivity type and defining a trench;
forming an insulating layer on the first semiconductor layer such that a thickness of the insulating layer in an upper portion of the trench is thicker than a thickness of the insulating layer in a lower portion of the trench;
removing the insulating layer in the lower portion of the trench while leaving at least part of the insulating layer in the upper portion of the trench;
forming a second semiconductor layer of a second conductivity type along an inner wall of the trench; and
forming a third semiconductor layer on the second semiconductor layer, the third semiconductor layer defining a void located in the trench.
